(19) United States
(12) Patent Application Publication
(10) Pub. No.: US 2005/0148193 A1
(43) Pub. Date: Jul. 7, 2005

(54) Photolithographic method for forming a structure in a semiconductor substrate

(75) Inventors: Markus Kirchhoff, Ottendorf-Okrilla (DE); Mirko Vogt, Dresden (DE); Stephan Wege, Dresden (DE); Frank Katzwinkel, Dresden (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munich (DE)

(21) Appl. No.: 10/496,102

(22) PCT Filed: Nov. 14, 2002
(86) PCT No.: PCT/DE02/04223

(30) Foreign Application Priority Data
Nov. 20, 2001 (DE) 101 56 865.7

(51) Int. Cl. H01L 21/8242

(52) U.S. Cl. 438/706

(57) ABSTRACT

To form a pattern in a semiconductor substrate, a buffer layer, which is formed as a carbon layer, is produced between a photoresist layer and an antireflective layer, which is formed on the substrate. The pattern is produced in the photoresist layer by means of a lithography step, and then it is transferred to the layers arranged below in a subsequent step.

### CLAIM FOR PRIORITY

This application claims priority to International Application No. PCT/DE02/04223 which was published in the German language on Jun. 5, 2003, which claims the benefit of priority to German Application No. 101 56 865.7-33, and filed in the German language on Nov. 20, 2001.

### TECHNICAL FIELD OF THE INVENTION

The invention relates to a patterning method for semiconductor technology in which a pattern is produced in a semiconductor substrate.

### BACKGROUND OF THE INVENTION

The fabrication of semiconductor components often requires a patterning to be carried out by etching in one method step, in which the sections which are to be removed are formed at least in part by a silicon oxide or silicon nitride. An example of this is the fabrication of semiconductor memory cells which have a trench capacitor and a select transistor. While the trench capacitor on one side is electrically connected to the select transistor by a buried strap, on the other side of the trench capacitor an insulation region (STI, “shallow trench isolation”) is produced, by means of which the trench capacitor is electrically insulated from an adjacent memory cell. The STI region is produced by means of a patterning step in which a surface section formed by a partial section of the trench capacitor which has previously been produced is removed. This means that not only silicon but also silicon oxide has to be etched, since the trench capacitor, in its upper section, has an insulation collar made from silicon oxide. Since there is generally a layer of silicon nitride at the surface of the section which is to be removed, it must therefore also be possible to etch silicon nitride by means of the etching process.

With regard to the production of STI regions during the fabrication of the abovementioned memory cells, reference is made, by way of example, to German laid-open specifications DE 199 41 148 A1 and DE 199 44 012 A1.

Considering the lateral dimensions of the trench capacitor, which are of the order of magnitude of 100-200 nm, the abovementioned process for producing the STI region places extremely high demands on the positional accuracy, dimensional stability and flank steepness of the etching process which is to be used, since the flank which is to be produced on the recess which is to be etched has to be located with an extremely low lateral positioning inaccuracy within the trench capacitor on the side remote from the buried strap.

To produce ultrafine patterns on the semiconductor surface and to maintain the minimum possible variation in the features sizes across the chip, the wafer or the batch, it is necessary for the reflection of light of the exposure wavelength at the wafer surface (photoresist-substrate interface) to be suppressed as completely as possibly, in order to rule out disruptive interference effects. This is particularly true of exposure wavelengths at and below 248 nm (248 nm, 257 nm) on account of the increasing reflectivity of the substrates and the increasing sensitivity of the resists which are used. Furthermore, to achieve the maximum possible depth of focus during exposure, the resist layer which is to be exposed must be as thin as possible. To achieve the transfer of the pattern, in particular with contact holes, it is necessary for the resist layer to be completely removed in the regions produced by the photolithographic mask, in order to be able to ensure exact transfer of the pattern and therefore a functional component during subsequent method steps.

During the photolithographic process, the form of the patterned resist after exposure is partly also determined by the base. If the base consists of silicon-containing insulator layers which have been deposited by plasma chemistry, for example SiO, SiON or SiN, the chemical composition of the region of these layers which is close to the surface can have a considerable influence on the results of photolithography. What are known as “resist feet” may be formed, connecting otherwise separate regions of resist, so that, during the transfer of the pattern into layers located beneath the resist, these resist feet cannot be etched, and therefore defective circuits or complete failure thereof result. This problem is made worse by the reduction in the feature size used and therefore the exposure wavelength which is to be used, since as a result the distance between adjacent regions of resist decreases.

EP 0 492 253 A1 describes a photographic patterning method in which two photoresist layers are used. An upper, relatively thin photoresist layer (top resist), after patterning with a silicon-containing agent, is made resistant to dry-etching in an oxygen plasma. In this subsequent dry-etching step, the pattern of the top resist is transferred, with the precise dimensions of the mask used for the patterning and with vertical flanks, into a lower, relatively thick photoresist layer (bottom resist). On account of the chemical amplification of the patterned top resist, this method has become known as CARL (chemical amplification of resist lines). The bottom resist serves as the actual mask during the etching of the substrate. The bottom resist itself then has to be removed in a special etching process, for example using O₂ of SO₂. Particularly during the etching of contact holes with very high aspect ratios, photoresist masks of this type have the major drawback that the polymers which are formed from the resist during the etching cannot be controlled. Consequently, the problem of the formation of the “resist feet” which has been outlined above can only be solved to a limited extent, since, with very small features, this leads to a considerable reduction of the etching process window, with the result that in this case, too, residues of resist (“resist feet”) remain on the substrate layer which is to be uncovered, and as a result at least partially prevent the pattern from being transferred into the substrate in subsequent process steps, and consequently the operational reliability of the component is no longer ensured.

Moreover, in the known prior art, a silicon-containing insulator layer, which is generally deposited by plasma chemistry, is produced between a semiconductor substrate and a photoresist layer. As a result of the exposure of the photoresist layer, an acid is formed in this resist layer. On account of the relatively high diffusion coefficient, this acid is active in virtually the entire region of the exposed resist layer, and the resist is readily soluble. On account of their chemical composition, the abovementioned layers below the resist layer can act as bases, and neutralise the acid formed in the resist layer in the transition region between the resist layer and the insulator layer below it. As a result, the solubility of the resist is reduced in this region and residues of resist remain at regions at which the insulator layer is to be uncovered and the resist layer is to be removed. These residues of resist reduce the width of the window for the region of the insulator layer which is actually to be opened up, and, in the case of small features, may even remain in place in such a manner that the insulator layer is still completely covered with a thin film of resist in the regions in which it is to be uncovered even after the exposure has taken place. This problem is made worse by the reduction in the feature size used and the exposure wavelength used for this purpose, particularly at wavelengths below 248 nm, in particular in 248 nm or 257 nm lithography.

### SUMMARY OF THE INVENTION

The invention provides a patterning method in which small features can be formed in the semiconductor substrate with a high level of accuracy and reliability.

In one embodiment of the invention, an antireflective layer is formed on the semiconductor substrate and then forming a buffer layer on the antireflective layer. The photoresist layer, which is exposed by a photolithography step so that a pattern is formed in the photoresist layer, is deposited on this buffer layer. In a further method step, this pattern is transferred into the layers below, which at least include the buffer layer, the antireflective layer and the semiconductor substrate.

This makes it possible to ensure that, even when very small features are to be transferred, the photoresist layer on the buffer layer below it is virtually completely removed in the desired regions.

It is advantageous if the pattern is transferred into the layers which lie below the photoresist layer by means of a single etching step, which is advantageously carried out by means of an anisotropic dry-etching process.

In a preferred exemplary embodiment, the buffer layer is formed as a thin carbon layer. The layer thickness is advantageously less 20 nm, in particular less than 10 nm, and preferably about 5 nm. It is advantageous for this buffer layer to be formed by means of a plasma-enhanced deposition process, for example by means of a PECVD process.

The method according to the invention is particularly suitable for the fabrication of insulation regions between trench capacitors which have been formed in the semiconductor substrate and which, in combination with a select transistor, are arranged as a memory cell of a memory component in a memory cell array. The regions which have been etched clear between the trench capacitors are filled with insulating material in order to produce the insulation regions.

### BRIEF DESCRIPTION OF THE DRAWINGS

Exemplary embodiments of the invention are explained in more detail below with reference to the drawings, in which:

FIGS. 1-4 illustrate the individual steps involved in the patterning method according to the invention.

### DETAILED DESCRIPTION OF THE INVENTION

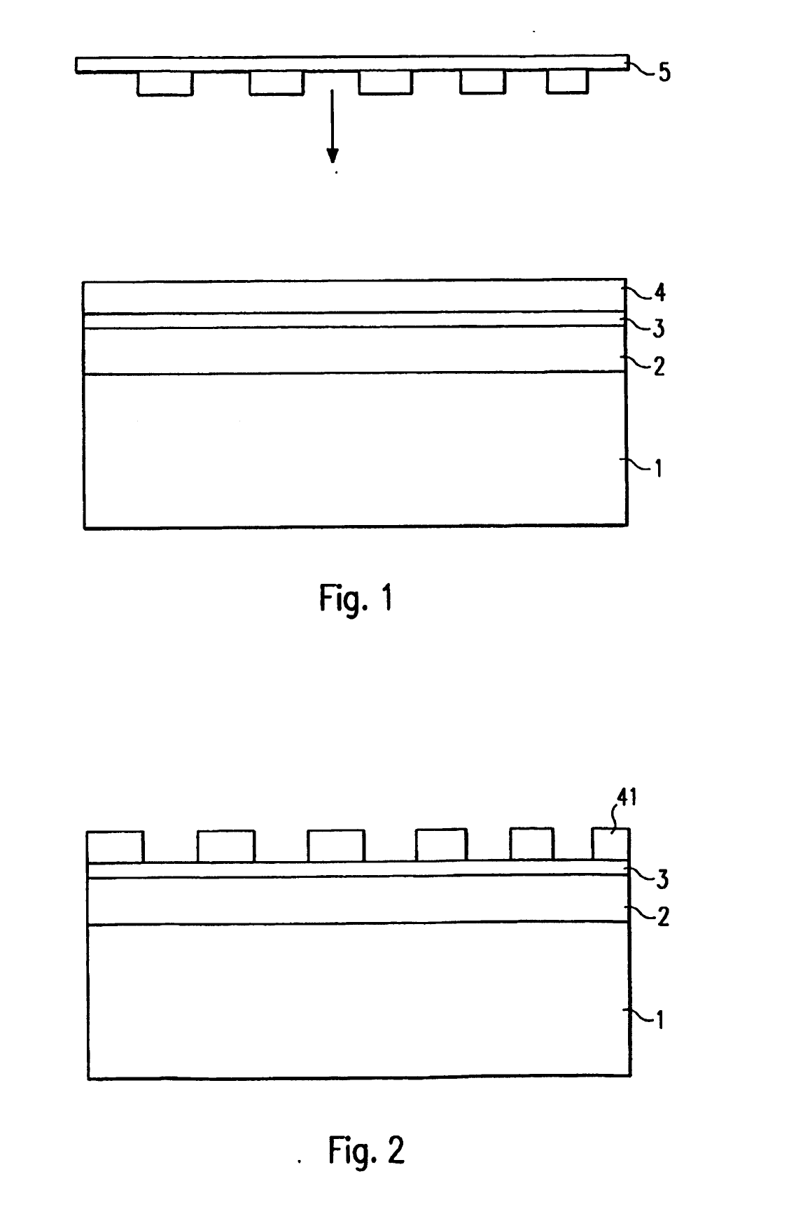

In accordance with FIG. 1, a semiconductor substrate 1 which is to be patterned is provided, which substrate may, for example, be a chip or wafer into which a matrix-like arrangement of trench capacitors has already been processed. The capacitors, in combination with in each case one select transistor, each form a memory cell. Insulation regions, which are also known as shallow trench isolation (STI) regions, are to be produced between the trench capacitor by means of the patterning process which is presented below by way of example. Since the sections which are to be removed to produce the insulation regions also each contain partial sections of the processed trench capacitors, it is consequently also necessary to etch silicon oxide, since the trench capacitors generally have an insulation collar consisting of silicon oxide.

In a subsequent method step, an antireflective layer 2 is produced on this semiconductor substrate 1. This antireflective layer 2 may, for example, be in the form of an organic layer, which includes an amino group (NH₂) at the surface, and may be applied by means of a known spin-on technique or may be formed as a SiO, SiON or SiN layer. During the exposure of the photoresist layer, this antireflective layer 2 is used to reduce fluctuations in intensity during the exposure and in this way to prevent the photoresist from being only partially developed. The layer 2 is formed with a layer thickness of less than 70 nm and advantageously with a layer thickness of approximately 45 nm.

A buffer layer, which in the exemplary embodiment is formed as a carbon layer 3, is deposited on the antireflective layer 2 by means of a plasma-enhanced deposition process. A PECVD (plasma-enhanced chemical vapour deposition process) may preferably be used as the deposition process. The carbon layer 3 can be deposited from a wide range or organic substances. An example which may be mentioned is a process in which C₃H₆ with a flow rate of 600 sccm and He with a flow rate of 325 sccm are introduced into a reactor in which the carbon layer 3 is deposited from the process gases at a temperature of 550° C., a pressure of 6 torr and a high-frequency power of 800 W. However, the buffer layer may also be formed as a carbon-containing layer. It is also possible to use an HDP (high density plasma) process for deposition of the carbon layer 3.

The carbon layer 3 is deposited with a layer thickness of less than 20 nm, in particular less than 10 nm. A layer thickness of approximately 5 nm has proven most advantageous for the exemplary embodiment. In general, the carbon layer 3 is to be designed to be as thin as possible, in order for the patterns produced to be transferred into the layer 1 to 3 by means of a single etching step. Furthermore, keeping the carbon layer 3 as thin as possible keeps the interfering reflections during exposure of the photoresist layer 4 which is formed on the carbon layer 3 to a low level. This photoresist layer 4 is produced from a negative or positive resist and is exposed by conventional exposure by means of a chromium mask 5.

As illustrated in FIG. 2, the regions which have been exposed in the exemplary embodiment are removed, so that resist regions 41 remain in place on the carbon layer 3.

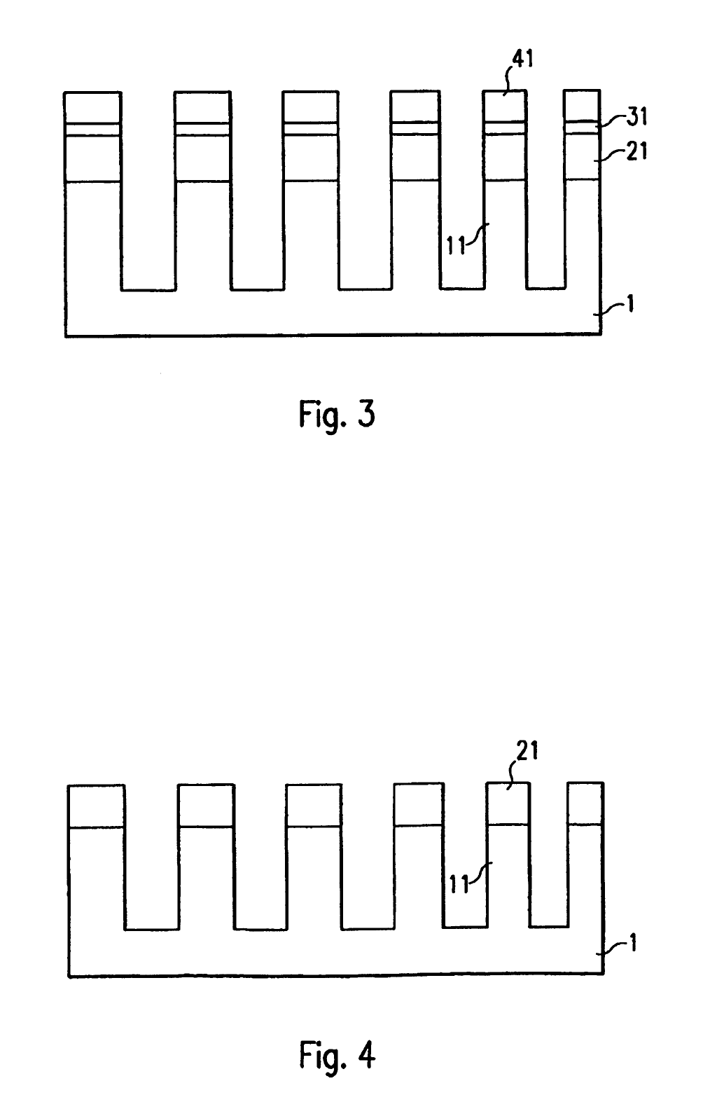

Then, as shown in FIG. 3, the actual process for patterning the semiconductor substrate 1 is carried out by means of an anisotropic dry-etching step. The dry-etching step may be carried out, for example, using an O₂ plasma, by means of which the photoresist layer 4, the carbon layer 3 and an antireflective layer 2 which has been formed from organic material are etched. By way of example, an F-containing and/or Cl-containing etching medium can be used for the etching of an inorganic antireflective layer 2 and the substrate 1. Unetched regions of the substrate 1, in which, by way of example, in the application mentioned above of the production of insulation regions, fully processed trench capacitors and select transistors of memory cells may be arranged, remain in place below the resist regions 41.

Finally, in one or more subsequent method steps, the resist regions 41 and the patterned regions 31 of the carbon layer 3 and the patterned regions 21 of the antireflective layer 2 can be removed. The regions 31 can be removed by means of a simple stripping process using an O₂ plasma. The substrate 1 which has been patterned in the form of the substrate regions 11 is illustrated in FIG. 4.

To produce insulation regions, the regions which have been uncovered in the substrate 1 and in the antireflective layer 2 have to be filled with a suitable insulation material in a subsequent method step, which is not shown.

The etching of the carbon layer 3 and of the layers 2 and 1 below it can advantageously be carried out using etching media which contain Cl or F. By way of example, Cl₂, BCl₃, SiCl₄, CCl₄, CHCl₃, CF₄, CHF₃, C₂F₆, C₃F₈, C₄F₈ or SF₆ can be used.

The buffer layer 3 is not intended to be designed as a hard mask for subsequent etching steps, but rather is used in particular to achieve chemical decoupling between the photoresist layer 4 and the antireflective layer 2 and to improve and make more precise the pattern profiles in the photoresist layer 4.

The chemical interaction between the resist of the resist layer 4 and the antireflective layer 2 on the semiconductor substrate 1 is at least prevented by the application of the thin buffer layer as carbon or carbon-containing layer 3 below the photoresist layer 4 to the extent that the pattern which is to be formed in the resist layer 4 by the lithography mask is produced reliably, and scarcely any “resist feet” remain in place on the buffer layer. In general terms, this can also be achieved by forming the buffer layer as a layer whose chemical composition is very similar to the chemical composition of the resist layer 4 formed above it. In particular, it is in this case advantageous if the buffer layer does not contain any amino groups with a basic action.

Therefore, the method according to the invention makes it possible to achieve a decoupling of chemical reactions between the photoresist layer 4 and the antireflective layer 2 and in this way to achieve accurate and reproducible resolution of very small dimensions by means of photolithography, with the result that these very small features can also be transferred to the substrate 1. By designing the buffer layer to be very thin, the reflection effects are kept at a low level and, furthermore, the transfer of the pattern from the photoresist layer 4 into all the layers below it can therefore be effected by means of a single etching step.

Therefore, the thickness of the buffer layer is to be configured in such a manner that this layer is at least sufficiently thick to allow chemical decoupling, but on the other hand has to be kept thin enough to be able to control reflection effects and etching problems. Forming this buffer layer 3 also allows the complex subsequent monitoring of the resist layer 4 following the exposure operation to be significantly reduced and further removal of material and renewed formation of the resist layer 4 and the lithography pattern which is desired therein to be reduced, with the result that considerably cost savings can be achieved.

The method according to the invention can be used not only for STI insulation but also for all other lithography steps involved in the fabrication of patterns in a semiconductor substrate.

1. A method for forming a pattern in a semiconductor substrate, comprising:
producing an antireflective layer of an organic substance on the semiconductor substrate;
forming a buffer layer on the antireflective layer;
depositing a photoresist layer on the buffer layer;
photolithographically producing a pattern in the photoresist layer; and
transferring the pattern into the antireflective layer, the buffer layer and the semiconductor substrate arranged below the photoresist layer.

2. The method according to claim 1, wherein the buffer layer is formed as a carbon layer or a carbon-containing layer.

3. The method according to claim 1, wherein the buffer layer is formed with a layer thickness of less than 20 nm.

4. The method according to claim 1, wherein the buffer layer is produced by a plasma-enhanced deposition process.

5. The method according to claim 4, wherein a PECVD process is used.

6. The method according to claim 1, wherein, during transferring, the pattern is substantially produced by a single etching step.
